(19) United States
(12) Patent Application Publication
(10) Pub. No.: US 2008/0160683 A1
(43) Pub. Date: Jul. 3, 2008

(54) SOURCE/DRAIN EXTENSIONS IN NMOS DEVICES

(76) Inventors: Aaron O. Vanderpool, Queen Creek, AZ (US); Mitchell C. Taylor, Lake Oswego, OR (US)

Correspondence Address: INTEL/BLAKELY, 1279 OAKMEAD PARKWAY, SUNNYVALE, CA, 94085-4040, US

(21) Appl. No.: 11/618,368

(22) Filed: Dec. 29, 2006

(51) Int. Cl. H01L 21/8232; H01L 21/335

(52) U.S. Cl. 438/142

(57) ABSTRACT

A method including implanting carbon and fluorine into a substrate in an area of the substrate between a source/drain region and a channel, the area designated for a source/drain extension; and a source/drain extension dopant following implanting carbon and fluorine, implanting phosphorous in the area. A method including disrupting a crystal lattice of a semiconductor substrate in an area of the substrate between a source/drain region and a channel designated for a source/drain extension; after disrupting, implanting carbon and fluorine in the area; and implanting phosphorous in the area. A method including performing a boron halo implant before implanting phosphorous to form N-type source/drain extensions. An apparatus including an N-type transistor having a source/drain extension comprising carbon and phosphorous, formed in an area of a substrate between a source/drain region of the transistor and a channel of the transistor.

### FIELD

Integrated circuit devices and methods of forming integrated circuit devices.

### BACKGROUND

In the formation of integrated circuits, a gate electrode may be utilized as a mask for forming source and drain junctions. The source and drain junctions may include an extension or tip that extends from the region underneath the gate electrode to a deeper source or drain region. The source/drain extension(s) tends to spread out the electrical field during operation of a transistor device. In an N-type transistor device, for example, an extension provides a source of electrons to spread out an electrical contact at the transistor drain and inhibit damage to a gate electrode dielectric.

In connection with N-type transistors, arsenic and phosphorous are commonly utilized as dopants for the deeper source drain junction. Phosphorous tends to diffuse more than arsenic because of transient enhanced diffusion (TED). The small size of the phosphorous atom and its tendency to diffuse through interstitial motion results in increased diffusion. The transient enhanced diffusion of phosphorous results in deeper N-typed source/drain regions.

As device geometries shrink, device channels and source/drain extensions shrink (both shorter in XZ dimension and shallower in an XY dimension). To make devices faster, the doping density of the source/drain extensions should be increased as device geometries shrink. This increase in density allows the N-type source/drain extension resistivity to be reduced. Reducing the resistivity of the N-type source/drain extensions allows transistor drive current densities to scale appropriately so long as the dose can be successfully activated during an anneal. The drive currents are directly related to the speed of the resulting transistors.

Currently, arsenic is used as the implant species for source/drain extensions in N-type devices. The current state of the art for an N-type extension layer is a spike annealed shallow (about three kiloelectro-volts (KeV) with a dose of about 2.0×10¹⁵ ions/cm²) arsenic layer with a carbon co-implant. The carbon co-implant tends to reduce the arsenic diffusion tail caused by arsenic TED. This produces an arsenic source/drain extension with a very sharp, shallow junction with a reasonable solubility level.

### BRIEF DESCRIPTION OF THE DRAWINGS

Features, aspects, and advantages of embodiments will become more thoroughly apparent from the following detailed description, appended claims, and accompanying drawings in which:

FIG. 1 is a schematic, cross-sectional side view of a semiconductor substrate including an active area defined by an isolation structure and a gate electrode on a surface of the substrate in the active area and shows implanting of a halo implant species.

FIG. 2 shows the structure of FIG. 1 following the formation of a halo implant in the substrate and shows implanting of a first implant species into an area designated for a source/drain extension.

FIG. 3 shows the structure of FIG. 2 following the implanting of the first implant species and shows implanting of a second implant species into an area designated for a source/drain extension.

FIG. 4 shows the structure of FIG. 3 following the implanting of the second implant species and shows implanting of a dopant species for a source/drain extension.

FIG. 5 shows the structure of FIG. 4 following the formation of source and drain extensions in the substrate.

FIG. 6 shows the structure of FIG. 5 following the formation of source and drain regions in the substrate defining the source/drain extensions in an area of the substrate between a source or drain region and the channel.

FIG. 7 shows a computer system including a package including a microprocessor coupled to a printed circuit board.

FIG. 8 shows a secondary ion mass spectometry (SIMS) plot of various N-type extension implants.

FIG. 9 is a magnified view of a portion of the SIMS plot of FIG. 8.

### DETAILED DESCRIPTION

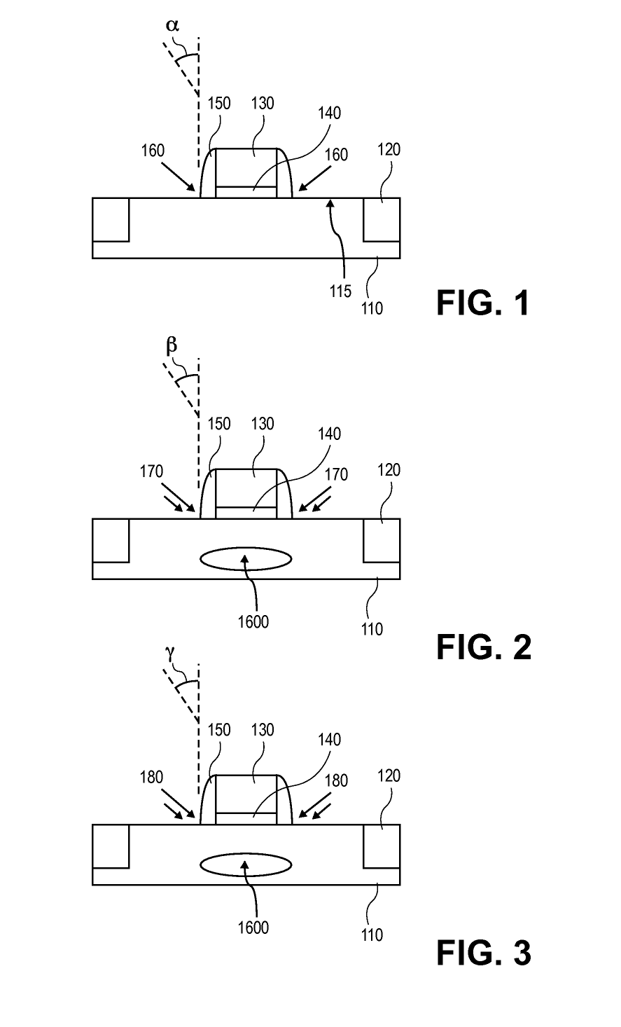

FIG. 1 shows a schematic, cross-sectional side view of a portion of a substrate, such as a portion of a semiconductor wafer. FIG. 1 shows substrate 110 of, for example, silicon, having shallow trench isolation structure 120 formed therein to define an active area for a transistor device. Overlying surface 115 of substrate 110 (top surface as viewed) is gate electrode 130 of, for example, a semiconductor (e.g., polycrystalline silicon) and/or metal material. Gate electrode 130 is separated from substrate 110 by gate dielectric 140 of, for example, silicon dioxide or other dielectric material.

Referring to FIG. 1, in one embodiment, following the formation and definition of gate electrode 130 in an active area of substrate 110, side walls spacers 150 of, for example, silicon dioxide are deposited on the side walls of gate electrode 130 (opposing lateral side walls that define a height or a thickness of gate electrode 130). A representative thickness of side wall spacers 150 is on the order of 20 angstroms (Å) to 50 Å to protect gate electrode 130 and gate dielectric 140 from damage due to implants as described below.

FIG. 1 also shows a halo implant species being introduced into substrate 110. In one embodiment, a halo implant may be utilized to inhibit current from flowing beneath a channel defined by an area in substrate 110 beneath gate electrode 130. Thus, in the context of forming a N-type metal oxide semiconductor (NMOS) transistor device, halo implant species 160 may be a positive halo such as indium or boron. FIG. 1 shows halo implant 160 being introduced at an angle, α₁ on the order of 20° relative to a perpendicular projection from surface 115 of substrate 110. As shown in FIG. 1, halo implant species is introduced at the edge of side wall spacers 150 at an energy to drive the species into a region below a designated device channel. In one embodiment, halo implant species 160 is a boron difluoride halo introduced at approximately 45 keV to approximately 8.0×10¹³ ions/cm² dose.

FIG. 2 shows a structure of FIG. 1 with halo implant 1600 formed therein at an area that will be below a device channel in substrate 110. One effect of the halo implant is that the halo implant species will tend to disrupt the lattice structure of substrate 110. For example, a silicon lattice bombarded by a halo implant will tend to be damaged in the sense that it will tend to amorphosize a portion of substrate 110. The amorphosized substrate may be recrystallized by a subsequent anneal. In one embodiment, the anneal does not follow until after the implantation of dopant species to form source/drain extensions.

FIG. 2 also shows an angled implantation of a carbon species into substrate 110. Carbon species 170 may be implanted at approximately 4 keV to about 2.0×10¹⁵ ions/cm² dose. Carbon species 170 may be introduced at an angle, β, on the order of 0° to 30° relative to a perpendicular projection from surface 115 of substrate 110. As shown in FIG. 2, carbon species 170 is introduced in an area of substrate 110 designated for a source/drain extension.

As noted above, a portion of substrate 110 may be amorphosized following introduction of a halo implant species. A portion of a carbon species introduced into an amorphous silicon will tend to become substitutional with silicon upon lattice regrowth. After regrowth, as the electrical dopant activation anneal increases in time and or temperature the interstitial silicon atoms will tend to displace or kick-out the substitutional carbon causing the carbon to occupy interstitial locations in the lattice where it no longer has the energy to become substitutional. Without wishing to be bound by theory, the presence of carbon in the lattice will tend to reduce TED by a dopant species such as phosphorous. The TED is reduced because the population of silicon interstitials in the lattice, which cause TED, is reduced and can no longer form interstitialcy complexes with a dopant species such as phosphorus. These interstitialcy complexes are the source of TED.

FIG. 3 shows the structure of FIG. 2 and illustrates a fluorine species implant. In one embodiment, fluorine species implant 180 is introduced at a sufficient dose to disrupt (e.g., damage) the lattice of substrate 110. Representatively, fluorine species implant 180 is introduced at an energy greater than 4 keV and less than 8 keV, for example, about 6 keV to about 2.0×10¹⁵ ions/cm² dose. Fluorine species implant 180 is implanted at an angle, γ, on the order of 0° to 30° relative to a perpendicular projection from surface 115 of substrate 110 into an area defined for a source/drain extension. As shown in FIG. 3, fluorine species implant 180 is introduced into substrate 110 in an area designated for a source/drain extension.

Without wishing to be bound by theory, fluorine tends to cluster with vacancies resulting from damaged silicon. As the electrical dopant activation anneal increases in time and or temperature the, silicon interstitial atoms tend to displace fluorine atoms and annihilate the vacancies as a Si—Si bond is more favorable than a fluorine vacancy complex. This effect will also tend to inhibit the TED of a subsequent source/drain extension implant. The TED is reduced because the population of silicon interstitials in the lattice, which cause TED, is reduced and can no longer form interstitialcy complexes with a dopant species such as phosphorus. These interstitialcy complexes are the source of TED.

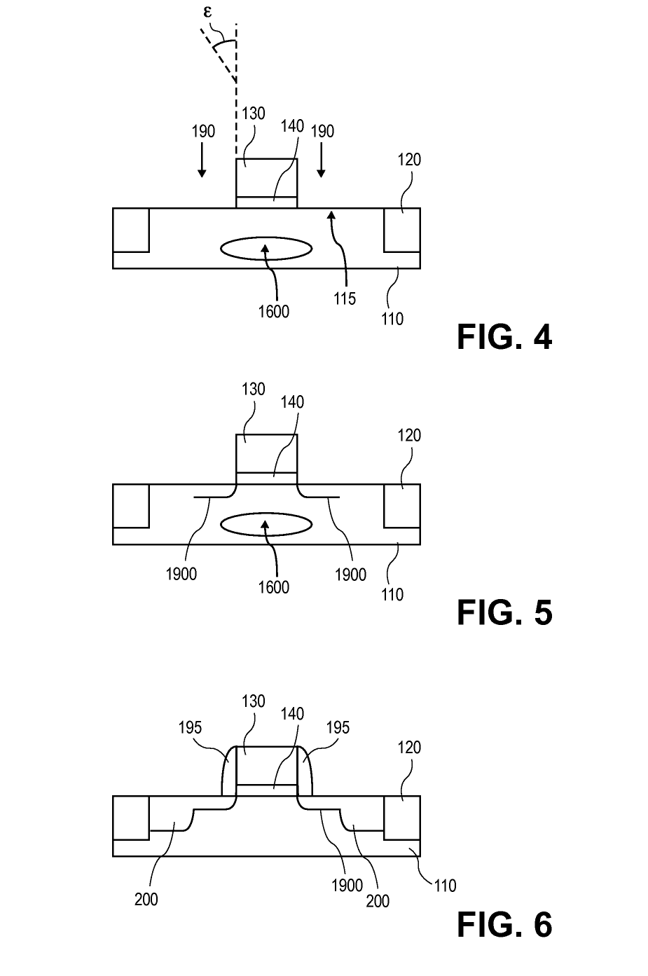

FIG. 4 shows the structure of FIG. 3 and shows source/drain extension implant 190 being introduced in substrate 110. In one embodiment, side wall spacers 150 may be removed prior to the introduction of source/drain extension implant 190. Source/drain extension implant 190 is, for example, a phosphorous species introduced at an angle, ε, of 0° to 20° relative to a perpendicular projection from surface 115 of substrate 110. Source/drain extension 190 is introduced into substrate 110 in an area designated for source/drain extensions adjacent gate electrode 130. In one embodiment, a source/drain extension of phosphorous is formed by introducing a phosphorous species at about 3 keV to about 2.0×10¹⁵ ions/cm² dose at 0°. In one embodiment, a source/drain extension species of phosphorous is a P₂⁺ dimer or other molecular n-type implant.

FIG. 5 shows the structure of FIG. 4 following the introduction of source/drain extension implant 190. Following the introduction of source/drain extension implant 190, substrate 110 may be annealed using, for example, a spike anneal and/or possibly a flash anneal (e.g., a 1060° C. spike anneal and a flash anneal in an N₂ environment). FIG. 5 shows source/drain extensions 1900 formed in substrate 110 beneath gate electrode 130 between source/drain extensions 1900.

FIG. 6 shows the substrate of FIG. 5 following the formation of source and drain regions adjacent source/drain extensions 1900. In one embodiment, side wall spacers 195 of, for example, silicon dioxide are formed on opposing lateral side walls of gate electrode 130 to a thickness on the order of a desired width of a source/drain extension (e.g., 10-15 nm for a 65 nm device (with at 40-45 nm gate length). Following the formation of side wall spacers 195, a source/drain implant of a material such as phosphorous or arsenic may be performed. FIG. 6 shows source/drain 200 formed in substrate 110. As illustrated, source/drain extensions 1900 are formed in substrate 110 between source/drain 200 and a channel region beneath gate electrode 130.

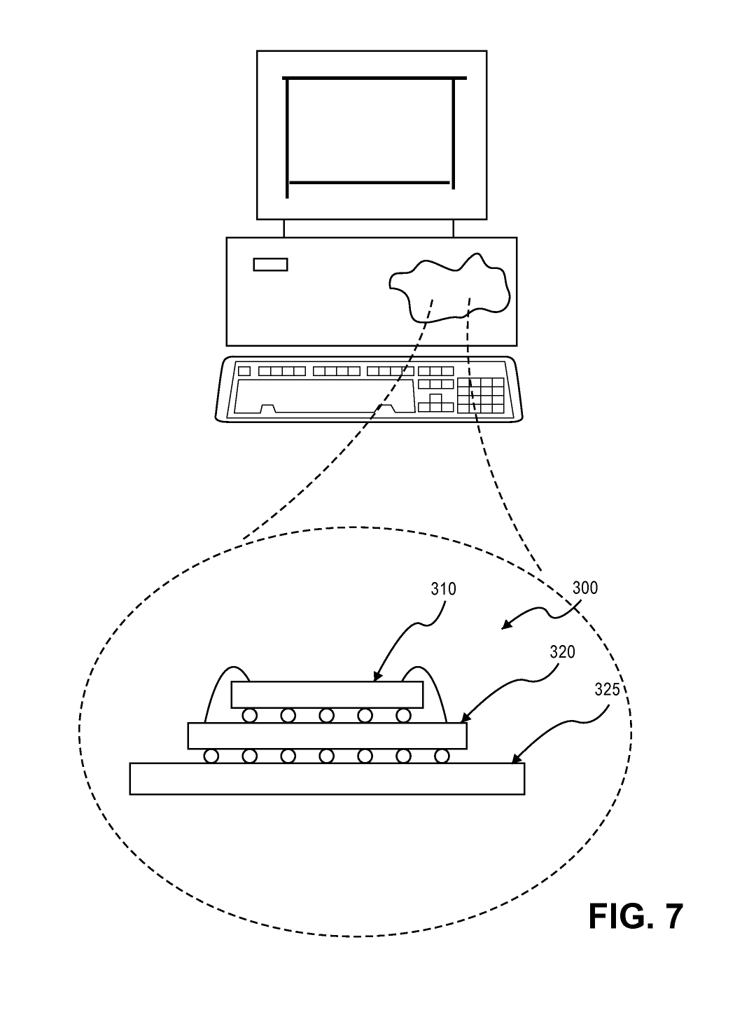

Further processing operations may be applied to the transistor device such as silicide processing and/or modification of the gate electrode material. Signal lines may be formed to the transistor device as known in the art. FIG. 7 shows a cross-sectional side view of an integrated circuit package that can be physically and electrically connected to a printed wiring board or printed circuit board (PCB) to form an electronic assembly. The electronic assembly can be part of an electronic system such as a computer (e.g., desktop, laptop, handheld, server, etc.), wireless communication device (e.g., cellular phone, cordless phone, pager, etc.), computer-related peripheral (e.g., printer, scanner, monitor, etc.), entertainment device (e.g., television, radio, stereo, tapes and compact disc player, video cassette recorder, motion picture experts group, Audio Layer 3 player (MP3), etc.), and the like. FIG. 7 illustrates the electronic assembly as part of a desktop computer. FIG. 7 shows electronic assembly 100 including die 310, physically and electrically connected to package substrate 320. Die 310 is an integrated circuit die, such as a microprocessor die, having, for example, transistor devices interconnected or connected to power/ground or input/output signals external to the die. The transistor structures include NMOS transistor devices formed as described above with reference to FIGS. 1-6 and the accompanying text, including NMOS transistor devices possibly as part of an inverter with PMOS transistor devices. Electrical contact points (e.g., contact pads on a surface of die 310) are connected to substrate package 320 through, for example, a conductive bump layer and/or wire bonds. Package substrate 320 may be used to connect die 310 to printed circuit board 325, such as a motherboard or other circuit board.

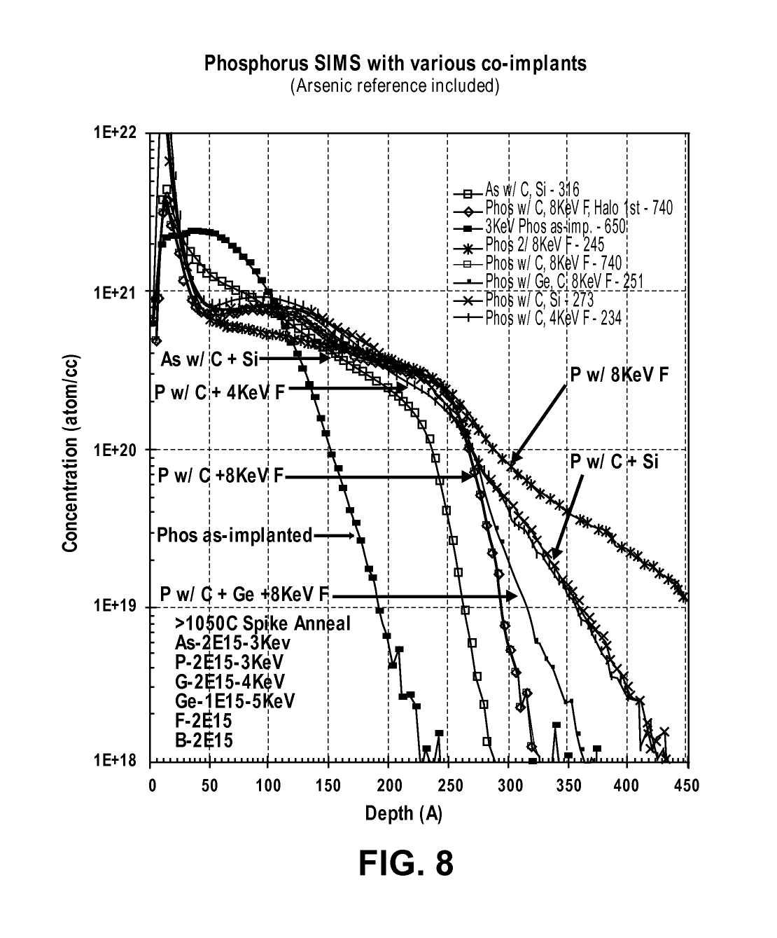

FIG. 8 shows a SIMS plot for several N-type source/drain extension layers. Referring to FIG. 8, according to current practices, an optimal N-type extension layer should be very shallow and form an abrupt junction with a maximum active dopant concentration. A depth into the substrate is taken when the dose crosses the 1E19 concentration on the SIMS plot of FIG. 8. The abruptness is a measurement of the slope of the active dopant concentration and the active dopant concentration can roughly be measured at a depth of about 200 Å. Referring to FIG. 8, the state of art arsenic source/drain extension (“As w/C+Si”) is 30 Å more shallow compared with a phosphorous source/drain extension introduced with carbon and fluorine following a halo (“P w/C+8 keV F”). However, the active concentration of phosphorous at a depth of 200 Å is 47 percent higher than the active concentration of arsenic according to the state of the art process. Without wishing to be bound by theory, this increase in active concentration may be due to the higher solubility of phosphorous in silicon as well as the presence of fluorine and carbon species. The result is that a sheet resistance of a phosphorous source/drain extension layer will tend to be lower than a sheet resistance of an arsenic source/drain extension producing a faster, more scalable transistor.

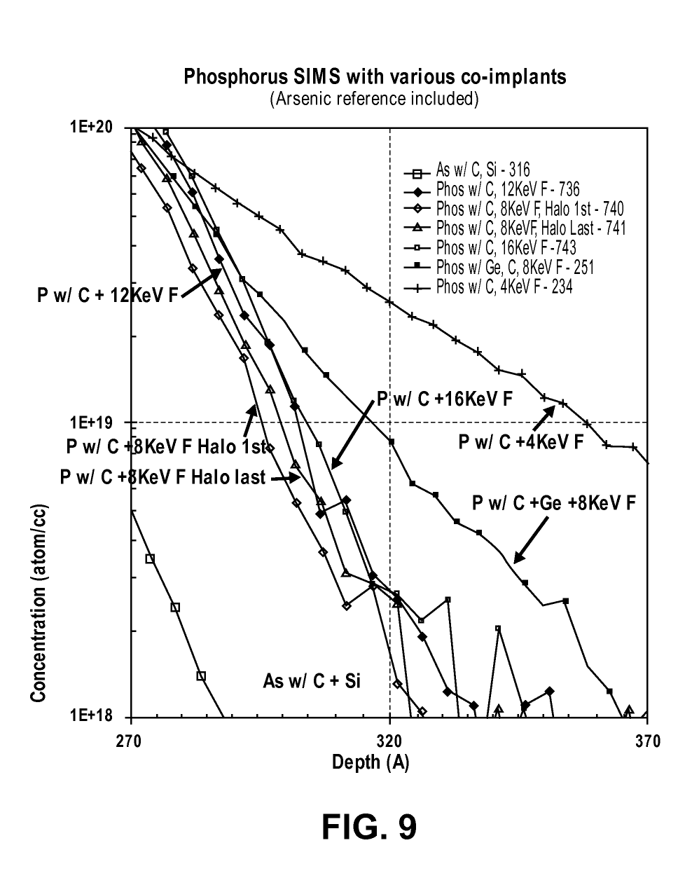

FIG. 9 shows a magnified view of the SIMS plot of FIG. 8. FIG. 9 also shows a profile of phosphorous source/drain extension introduced with carbon and fluorine before a halo implant (“Halo Last”) and after a halo impact (“Halo 1st” (also shown in FIG. 8)). FIG. 9 shows that reducing the flowing co-implant energy to 8 keV or less (but greater than 4 keV) reduces diffusion and performing the halo implant prior to the carbon and fluorine implant is advantageous in one embodiment.

In the above embodiment, the substrate (e.g., silicon) is disrupted prior to the introduction of the implant species. One way this is done is through a halo implant. An alternative would be to use a silicon or a germanium implant into, for example, a silicon substrate. A germanium species tends to add local strain to a lattice and is more soluble in silicon than carbon. Germanium would, therefore, also reduce the TED of phosphorous and, in another embodiment, could be substituted for, or added to, the carbon implant species.

In the preceding detailed description, reference is made to specific embodiments thereof. It will, however, be evident that various modifications and changes may be made thereto without departing from the broader spirit and scope of the following claims. The specification and drawings are, accordingly, to be regarded in an illustrative rather than a restrictive sense.

What is claimed is:

1. A method comprising:
implanting carbon and fluorine into a substrate in an area of the substrate between a source/drain region and a channel, the area designated for a source/drain extension; and
following implanting carbon and fluorine, implanting phosphorous in the area.

2. The method of claim 1, wherein prior to implanting carbon and fluorine, the method further comprises:
amorphosizing a portion of the substrate in the area.

3. The method of claim 2, wherein amorphosizing comprises implanting a halo implant.

4. The method of claim 2, wherein the substrate comprise silicon and amorphosizing comprises implanting germanium.

5. The method of claim 1, including implanting fluorine at an energy of more than four kilo-electron-volts to eight kilo-electron volts.

6. The method of claim 5, including implanting fluorine at a dose of about 2E15 atoms/cm².

7. The method of claim 1, including performing a halo implant before implanting fluorine.

8. A method comprising:
disrupting a crystal lattice of a semiconductor substrate in an area of the substrate between a source/drain region and a channel designated for a source/drain extension;
after disrupting, implanting carbon and fluorine in the area; and
implanting phosphorous in the area.

9. The method of claim 8, wherein disrupting comprises amorphosizing a portion of the substrate in the area.

10. The method of claim 8, wherein amorphosizing comprises implanting a halo species.

11. The method of claim 8, including implanting fluorine at a sufficient dose to damage the lattice.

12. The method of claim 8, wherein fluorine is implanted at a dose of about 2E15 atoms/cm².

13. The method of claim 8, wherein fluorine is introduced at an energy of more than four kilo-electron volts to eight kilo-electron-volts.

14. The method of claim 8, wherein disrupting comprises introducing germanium into the substrate.

15. An apparatus comprising:
an N-type transistor having a source/drain extension comprising carbon and phosphorous, formed in an area of a substrate between a source/drain region of the transistor and a channel of the transistor.

16. The apparatus of claim 15, wherein the source/drain extension comprises fluorine.

17. The apparatus of claim 15, wherein a concentration of phosphorous is on the order of 2E15 ions/cm².

18. The apparatus of claim 15, wherein carbon is deeper than said phosphorus.

19. The apparatus of claim 15, wherein fluorine is deeper than said phosphorus.

20. A method comprising:
performing a boron halo implant before implanting phosphorous to form N-type source/drain extensions.

21. The method of claim 20, further comprising implanting carbon to a depth deeper than the phosphorus implant.

22. The method of claim 20, further comprising implanting fluorine to a depth deeper than the phosphorus implant.
